(19) United States
(12) Patent Application Publication
(10) Pub. No.: US 2010/0174503 A1
(43) Pub. Date: Jul. 8, 2010

(54) Monitoring NFET/PFET Skew in Complementary Metal Oxide Semiconductor Devices

(75) Inventors: Bruce Balch, Saranac, NY (US); Anthony Wayne Fazekas, Durham, NC (US); Mark C.H. Lamorey, South Burlington, VT (US); Jeffrey H. Oppold, Richmond, VT (US); Joseph James Oler, JR., Jericho, VT (US); Chirstopher Daniel Parkinson, Raleigh, NC (US)

Correspondence Address: IBM MICROELECTRONICS;INTELLECTUAL PROPERTY LAW, 1000 RIVER STREET, 972 E, ESSEX JUNCTION, VT, 05452, US

(73) Assignee: International Business Machines Corporation, Armonk, NY (US)

(21) Appl. No.: 12/349,698

(22) Filed: Jan. 7, 2009

(51) Int. Cl. G01R 29/02; G21C 17/00; H03K 3/03

(52) U.S. Cl. 702/79; 702/182; 331/57

(57) ABSTRACT

An apparatus for directly measuring performance offset of NFET transistors with respect to PFET transistors in CMOS device processing includes a ring oscillator whose frequency is used to measure random across chip variations, as well as correlated across chip variations; a balanced inverter having a input driven by the ring oscillator, wherein the balanced inverter is designed to be formed such that a current drive capability of one or more NFET devices of the inverter is substantially equal to a current drive capability of one or more PFET devices of the inverter at a given operating temperature; and a capacitor coupled to an output of the inverter, with a voltage across the capacitor indicative of whether a skew exists between NFET device performance and PFET device performance.

### BACKGROUND

The present invention relates generally to integrated circuit (IC) designs and performance and, more particularly, to a method and apparatus for determining across chip variation (ACV) on an actual circuit by monitoring n-type field effect transistor (NFET) versus p-type field effect transistor (PFET) skew in CMOS devices, to create more accurate timing models for IC designs.

ACV is the term used to describe how two or more transistors or identical circuits will behave on a given die or chip. Variation Aware Timing has been introduced to take into account Random Uncorrelated (physical effects), and Random Correlated (Systematic Offsets between devices across a chip). Different measurements of key parameters (e.g., frequency) from multiple instances of identical circuits on the same die are characterized to understand correlated and uncorrelated ACV components.

Within a typical CMOS transistor circuit the performance of an NFET versus the performance of a PFET will vary. Because of the common process steps employed in the manufacture and production of CMOS devices, the performance of one type of transistor in a CMOS circuit will generally track that of the other type of transistor in the circuit.

Using difference measurements from across a die, reticle or wafer are applied using statistical techniques used to measure random components of ACV that can either be correlated (a.k.a. systematic) to a physical affect or are statistically independent (a.k.a. pure random/uncorrelated) from any physical effect. Correlated (or systematic) ACV shall refer to the portion of the ACV that may be correlated to variation in specific electrical or physical attributes, such as Vₜ and L_{eff}. Uncorrelated ACV shall refer to the portion of the Total ACV that is statistically independent of any known electrical or physical effect.

As a result, the overall performance of a CMOS circuit may be monitored through the use of a test structure such as a ring oscillator, which can facilitate obtaining circuit delay measurement parameters such as resistance, capacitance, frequency and average direct current (DC) drawn. However, some process steps in the manufacturing process are not common, and thus the use of a ring oscillator by itself will not provide any indication of a performance offset between an NFET device and a PFET device within a CMOS device. That is, if either the NFET devices or the PFET devices (or both) are faster than expected, then the frequency of the oscillator will be faster than expected. Conversely, if either the NFET devices or the PFET devices (or both) are slower than expected, then the frequency of the oscillator will be slower than expected. Stated another way, there is no way to directly determine (in this manner) any performance offsets between the NFET devices with respect to the PFET devices because the monitoring circuits use both devices.

Accordingly, it would be desirable to be able to implement a simple scheme for directly measure a current drive mismatch between NFET and PFET devices within a CMOS circuit.

### SUMMARY

According to one embodiment of the present invention, a device is provided. The device includes a silicon chip including circuit elements disposed thereon and a plurality of interleaved ring oscillators disposed on a surface of the silicon chip. The plurality of interleaved ring oscillators include a first interleaved ring oscillator that includes a plurality of identical cells. A first half of the plurality of identical cells are coupled to one another to form a clockwise ring and a second half of the plurality of identical cells are coupled to together to form a counter clockwise ring and wherein each cell in the first half is separated from another cell in the first half by a cell in the second half.

In an exemplary embodiment, an apparatus for directly measuring performance offset of NFET transistors with respect to PFET transistors in CMOS device processing includes a ring oscillator; a balanced inverter having a input driven by the ring oscillator, wherein the balanced inverter is designed to be formed such that a current drive capability of one or more NFET devices of the inverter is substantially equal to a current drive capability of one or more PFET devices of the inverter at a given operating temperature; and a capacitor coupled to an output of the inverter, with a voltage across the capacitor indicative of whether a skew exists between NFET device performance and PFET device performance.

Another embodiment of the present invention is directed to a method for determining correlated across chip variation. The method of this embodiment includes placing a plurality of interleaved ring oscillators over the surface of a silicon chip in a predetermined pattern; measuring the periods of oscillation of each interleaved ring oscillators; based on the periods of oscillation of each interleaved ring oscillators, calculating a total across chip variation value; based on the periods of oscillation of each interleaved ring oscillators, calculating an uncorrelated across chip variation value; and calculating the correlated across chip variation value by subtracting the uncorrelated across chip variation value from the total across variation value.

Another embodiment of the present invention is directed to a method of conforming modeled across chip variation data to actual correlated across chip variation values. The method of this embodiment includes placing a plurality of interleaved ring oscillators over the surface of a silicon chip in a predetermined pattern; measuring the periods of oscillation of each interleaved ring oscillators; based on the periods of oscillation of each interleaved ring oscillators, calculating a total across chip variation value; based on the periods of oscillation of each interleaved ring oscillators, calculating an uncorrelated across chip variation value; calculating the correlated across chip variation value by subtracting the uncorrelated across chip variation value from the total across variation value; correlating the modeled across chip variation data to the correlated across chip variation value; determining if the modeled across chip variation data matches the correlated across chip variation value; and modifying the modeled across chip variation data in the event that the modeled across chip variation data does not match the correlated across chip variation value.

In another embodiment, a method of directly measuring performance offset of NFET transistors with respect to PFET transistors in CMOS device processing, includes driving an input of a balanced inverter by a ring oscillator, wherein the balanced inverter is designed to be formed such that a current drive capability of one or more NFET devices of the inverter is substantially equal to a current drive capability of one or more PFET devices of the inverter at a given operating temperature; and coupling a capacitor to an output of the inverter, with a voltage across the capacitor indicative of whether a skew exists between NFET device performance and PFET device performance.

Additional features and advantages are realized through the techniques of the present invention. Other embodiments and aspects of the invention are described in detail herein and are considered a part of the claimed invention. Refer to the description and drawings for a better understanding of the advantages and features of the invention.

### BRIEF DESCRIPTION OF THE DRAWINGS

The subject matter which is regarded as the invention is particularly pointed out and distinctly claimed in the claims at the conclusion of the specification. The forgoing and other features, and advantages of the invention are apparent from the following detailed description taken in conjunction with the accompanying drawings in which like elements are numbered alike in the several Figures:

FIG. 1 is a schematic diagram that shows an example of an interleaved ring oscillator according to one embodiment of the present invention;

FIG. 2 is a schematic diagram that shows a example of a complete half-ring of a interleaved ring oscillator according to one embodiment of the present invention;

FIG. 3 is a schematic diagram that shows a chip having a plurality of interleaved ring oscillators disposed thereon; and

FIG. 4 is a data flow diagram that shows a method according to one embodiment of the present invention.

FIG. 5 is a schematic block diagram illustrating an apparatus for monitoring NFET versus PFET skew in CMOS devices, in accordance with an embodiment of the invention;

FIG. 6(a) is a graph of the voltage of the capacitor of the skew monitoring apparatus in FIG. 1, particularly illustrating an exemplary NFET/PFET skew where the PFET devices have a relatively greater drive strength;

FIG. 6(b) is a graph of the voltage of the capacitor of the skew monitoring apparatus in FIG. 5, particularly illustrating an exemplary NFET/PFET skew where the NFET devices have a relatively greater drive strength;

FIG. 7(a) is a schematic diagram of an exemplary inverter design for the balanced inverter of the skew monitoring apparatus in FIG. 5; and

FIG. 7(b) is a schematic diagram of another exemplary inverter design for the balanced inverter of the skew monitoring apparatus in FIG. 5.

### DETAILED DESCRIPTION

One embodiment of the present invention utilizes multiple interleaved ring oscillators placed around the surface of a chip to gather correlated and uncorrelated ACV for the chip. This information may be used in an MHC (Model-to-Hardware Correlation) process. MHC is a process of validating the ability to accurately model real world quantities as observed in actual hardware. As used herein, the term “chip” shall refer to an integrated circuit (also known as IC, microcircuit, microchip, or silicon chip) that is a miniaturized electronic circuit (consisting mainly of semiconductor devices, as well as passive components) that has been manufactured on the surface of a thin substrate of semiconductor material.

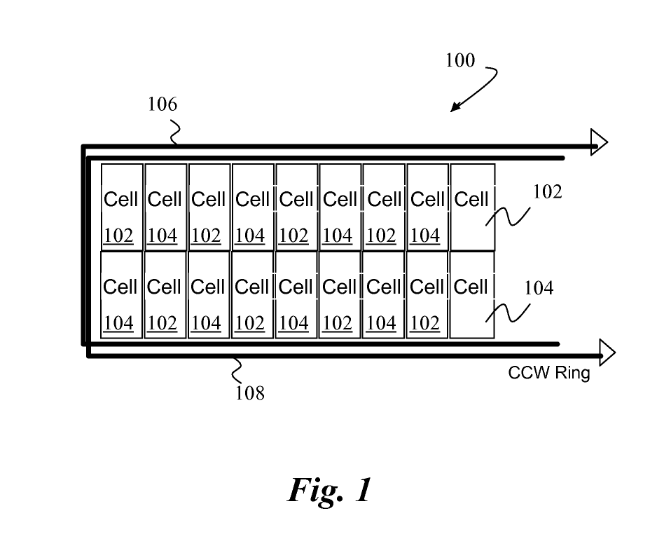

As discussed above, a basic component of an embodiment of the present invention is an interleaved ring oscillator. FIG. 1 is a schematic diagram that shows an example of an interleaved ring oscillator 100 according to one embodiment of the present invention. The ring oscillator 100 includes clockwise cells 102 and counter clockwise cells 104. In one embodiment, the clockwise cells 102 and counter clockwise cells 104 for any particular ring oscillator 100 are identical. In one embodiment, each clockwise cell 102 is connected to its neighboring clockwise cells 102 so that a signal propagates in the direction indicated by clockwise arrow 106. Similarly, each counter clockwise cell 104 is connected to its neighboring counter clockwise cells 104 so that a signal propagates in the direction indicated by counter clockwise arrow 108. In one embodiment, the wiring between each cell is identical. The cells may be n-type or p-type FETs, for example.

In one embodiment, an interleaved ring oscillator 100 according to embodiments of the present invention includes the two rings (clockwise and counter clockwise) such that each effectively occupies the same space due to a interleaved design and, thus, may allow for canceling out correlated ACV. In one embodiment, there may be multiple configurations of the particular cells to examine different effects.

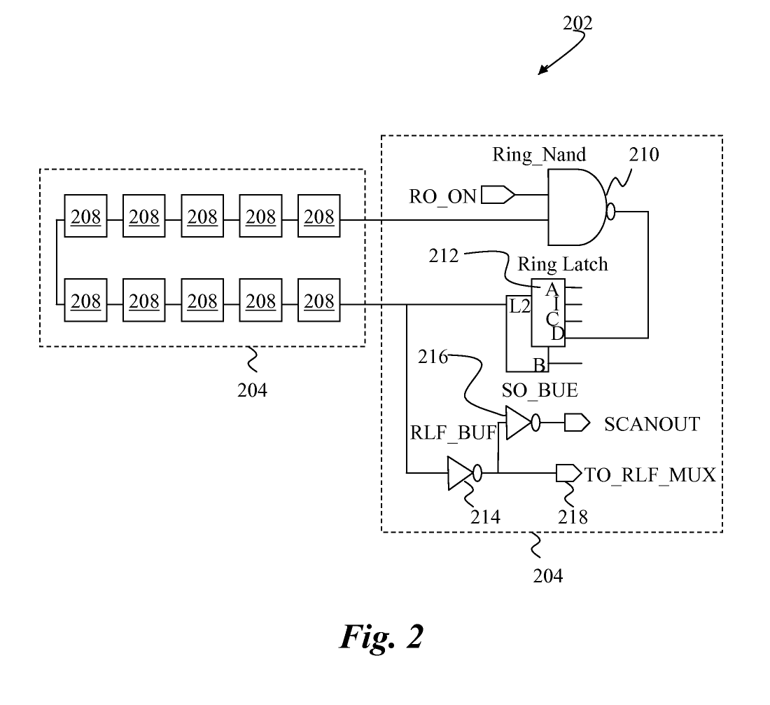

FIG. 2 is a schematic diagram that shows the basic structure used for a single interleaved ring oscillator 100 (FIG. 1). Each ring 202 consists of two main portions, the oscillator portion 204 and the overhead portion 206. The oscillator portion 204 contains the main portion of the ring and is made up of the desired quantity of identical stages 208 of the circuit under evaluation. Each stage 208 is a particular type of cell as described above.

The overhead portion 206 includes the remaining logic required to make the oscillator function. RING_NAND 210 is coupled to a first end of the ring 204 and is used to start and stop oscillation. RING_LATCH 212 is coupled to a second end of the ring 204 and is inserted for logic test methodology compliance. RLF_BUF 214 and SO_BUF 216 are also connected to the second end of the ring 204 and are used to buffer the critical ring path signals from the output. The output 218 (TO_RLF_MUX) is connected to a multiplexer (not shown in FIG. 2) that is used to steer the desired output to a frequency divider for driving the output across, and ultimately off, the chip. The inverted RLF output does not affect the results since only the oscillation period is of interest.

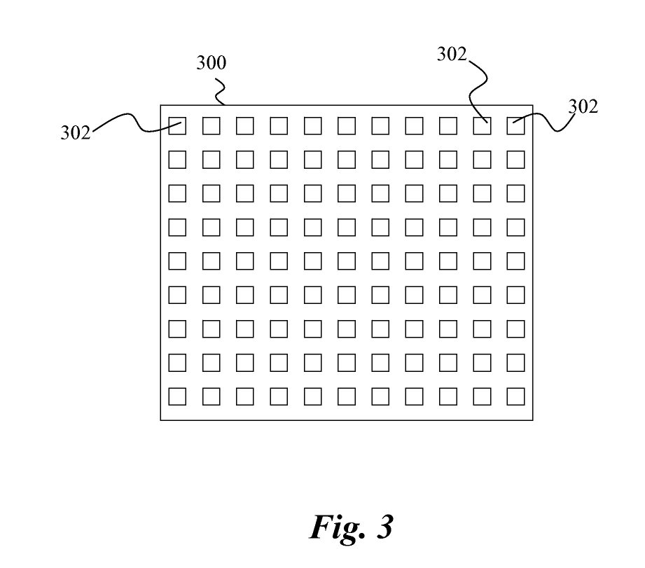

FIG. 3 is a schematic diagram that shows an example of a chip 300 having a plurality of interleaved ring oscillators 302 disposed thereon. Of course, the arrangement shown in FIG. 3 is illustrative only and any other configuration may be used, and each interleaved ring oscillator may be of any type as described above.

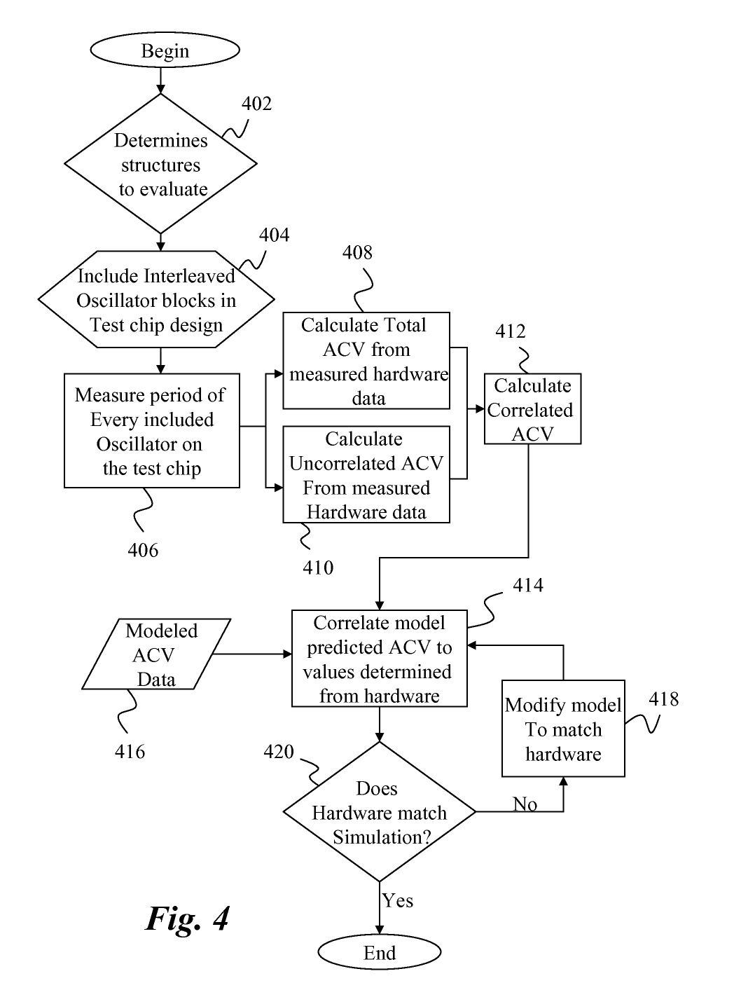

FIG. 4 shows a data flow diagram according to one embodiment of the present invention. This data flow diagram details how results of information from the interleaved ring oscillators may be used to improve computer models to match actual hardware results. At a block 402 the structures to be evaluated are determined. This may be done, for example, by choosing one or more circuits that are being created for production for which extensive analysis may need to be done.

At a block 404, a plurality of interleaved ring oscillators are included on a particular test chip. As discussed above, the location of the interleaved ring oscillators may vary. At a block 406, the period of the all of the placed chips is determined. In one embodiment, the period of each chip may include two periods, a clockwise period and a counter clockwise period.

At a block 408, the total ACV is calculated from information measured in step 406. This may be accomplished by first finding the mean of the clockwise and counterclockwise periods for each interleaved ring oscillator. The difference between the periods for all unique combinations of interleaved ring oscillators is then determined. In one embodiment, if there are n interleaved ring oscillators on the chip this will result in (n²−n)/2 differences (combination of n items taken two at time where n is the number of placed ring oscillators). For example, if oscillators O1, O2, O3 and O4 are present, the following differences: (OP1−OP2), (OP1−O3), (OP1−OP4), (OP2−OP3), (OP2−OP4) and (OP3−OP4) are calculated where OP is the average period for the particular oscillator. Of course, each of the differences may be represented as an absolute value of the difference. The distribution of the differences may be evaluated to determine the sigma value. The mean will be zero and the three sigma value is specified as the total ACV. In one embodiment, the total ACV is specified as a percentage of the mean period for the entire chip to allow its general use.

At a block 410, the uncorrelated ACV is calculated from the information measured at block 406. Calculation of the uncorrelated ACV includes calculating the difference between the periods of the two rings making up the interleaved ring oscillator (CW ring and CCW ring) for all interleaved oscillators on the chip. For example, if O1, O2, O3 and O4 are present, the values (B1CW−B1CCW), (B2CW−B2CCW), (B3CW−B3−CCW), (B4CW−B4CCW) are calculated where B is the period in the direction specified. These data distributions are then evaluated to find the distribution and determine the sigma. The mean will be zero, and the plus and minus three sigma values are specified as the uncorrelated ACV. In one embodiment, the uncorrelated ACV is specified as a percentage of the mean period for the entire chip to allow it's general use.

In one embodiment, multiple test chips may be used and the processes in blocks 402-410 may be repeated for each chip. For each chip, the correlated ACV value is determined at a block 412. The correlated ACV may, in one embodiment, be equal to the difference between the total ACV and the uncorrelated ACV.

In FIG. 4, block 416 represents modeled ACV data. Block 414 represents the modeled value correlated to the calculated ACV values from hardware. If the modeled/simulated values match the values calculated from hardware, the process ends. Otherwise, at a block 418 the model to create the ACV data is altered and new modeled ACV data 416 is created. Processing then returns to block 414.

The preceding description has dealt with a singe chip. Of course, data could be retrieved for any number of chips. In some embodiments, interleaved ring oscillator may include results from wafers, reticles, or each chip in a reticle including multiple chips.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one ore more other features, integers, steps, operations, element components, and/or groups thereof.

In addition, disclosed herein is a method and structure for measuring the current drive mismatch between the NFET and PFET devices in a CMOS device. Briefly stated, a periodic input source such as a ring oscillator is used to drive an inverter specifically designed to have a balanced current drive with respect to the NFET and PFET devices comprising the inverter. The steady state output voltage of the inverter is held across a capacitive load coupled to the inverter output, the value of which is used to determine any mismatch in the NFET and PFET current drive Iₒₙ. The present approach has additional advantages in that it draws only device off current in standby mode and can be modified into an existing application specific integrated circuit (ASIC) test flow.

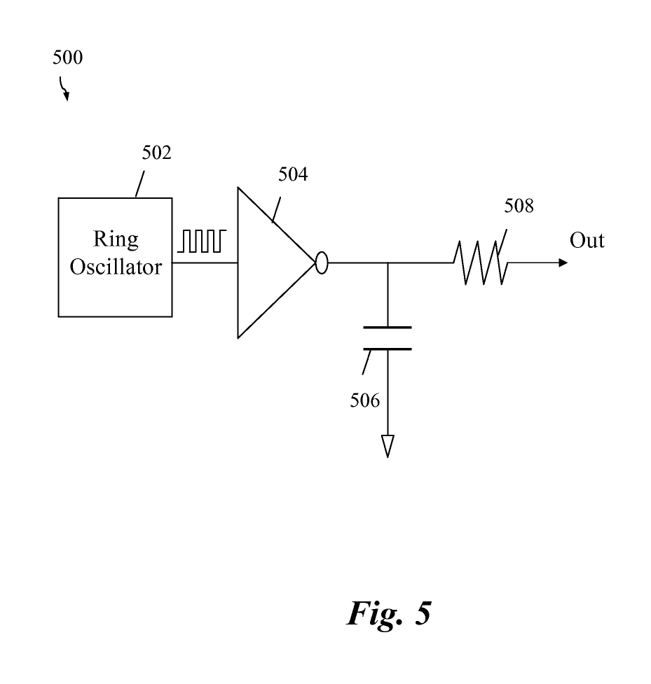

FIG. 5 is a schematic block diagram illustrating an apparatus 500 for monitoring NFET versus PFET skew in CMOS devices, in accordance with an embodiment of the invention. As shown in FIG. 5, a ring oscillator 502 acts an input signal source to a balanced inverter 504 comprising one or more NFET devices and one or more PFET devices. As discussed in further detail below, the inverter 504 is balanced in the sense that the geometries of the NFET(s) and PFET(s) making up the inverter are designed such that under nominal process conditions, the NFET current drive matches the PFET current drive at a given operating temperature. In addition, a capacitor 506 is coupled to the output of the balanced inverter 504.

The capacitor 506 may be “off chip” with respect to the inverter 504 and ring oscillator 502. Alternatively, however, the capacitor 506 could also be formed on the same chip as the CMOS circuitry. As also explained in further detail below, the capacitor 106 is sized such that the charge storage capability thereof is substantially larger than the up or down drive capability of the inverter for the maximum possible oscillator frequency. The steady state output voltage of the capacitor 506 is used to determine the NFET/PFET skew, and may be monitored at, for example, output port “Out.” A resistance 508 is modeled in FIG. 5 and may represent, for example, FET on resistance of the inverter 504.

In operation, the ring oscillator 502 produces an output signal having a substantially 50% duty cycle (with some maximum acceptable tolerance thereof), as well as an acceptable variation in output frequency in accordance with acceptable ranges associated with ring oscillator frequency. As indicated above, the capacitor 506 has a charge storage capability that is selected to be substantially greater than the on current for the NFET or PFET portion of the inverter 504 for any acceptable ring oscillator frequency. Preferably, the design criteria for the apparatus is governed by the following equation:

$$\frac{( {C}_{min} ) ( {V}_{int} / 2 )}{( {T}_{period \_ Max} / 2 )} >> FETIon\_Max ;$$

wherein Cₘᵢₙ represents a minimum capacitance value for the capacitor 506, Vᵢₙₜ represents an internal power supply voltage used by the CMOS circuitry (e.g., the ring oscillator 502 and inverter 504), T_{period}_{_{—}}_{Max} corresponds to the speed or period of the fastest ring oscillator frequency, and FETIon_Max represents the maximum FET drive current of the inverter devices.

In an exemplary embodiment, this ratio of minimum capacitance and internal voltage to the ring oscillator period exceeds the maximum FET on current by at least a factor greater than 1, more preferably by a factor greater than 5 and, most preferably, by at least a factor of 10. Regardless of any skew therebetween, the NFET and the PFET will still try to respectively output a logic high and logic low, which will be very close to Vᵢₙₜ and ground, respectively, in a steady state solution. However, the drive current will pull the capacitor up or down to Vᵢₙₜ or ground will vary with the performance skew.

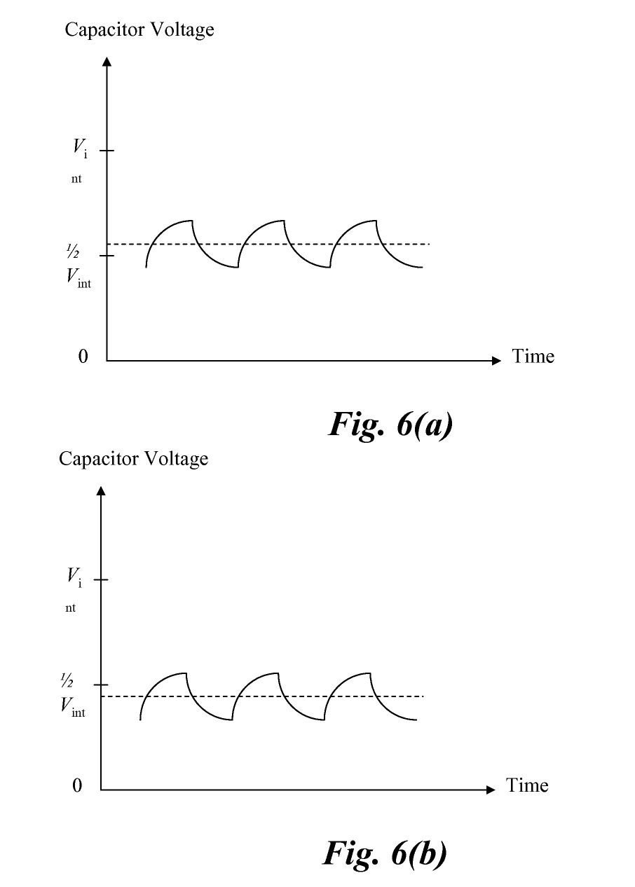

Depending upon the steady state average voltage on the capacitor 506, if there is any skew with respect to the drive current strength of the nominally balanced inverter, this will provide a good indication of NFET to PFET performance offsets within the CMOS fabrication process. For example, FIG. 6(a) is a graph representing the output voltage of the capacitor 506 (with the dashed line representing the steady state voltage on the capacitor 506). In this case, there is a detected NFET/PFET skew wherein the drive strength of the pull up PFET devices exceeds the drive strength of the pull down NFET devices. That is, the steady state voltage on the capacitor 506 is slightly above half the value of the internal supply voltage.

Conversely, FIG. 6(b) illustrates an example of another NFET/PFET skew condition, where this time the drive strength of the pull down NFET devices exceeds that of the pull up PFET devices. This is indicated by the steady state capacitor voltage (dashed line) wherein the steady state voltage on the capacitor 506 is slightly below half the value of the internal supply voltage. In the event the steady state capacitor voltage was equal to half the internal supply voltage, this would be indicative of no (or substantially no) NFET to PFET skew.

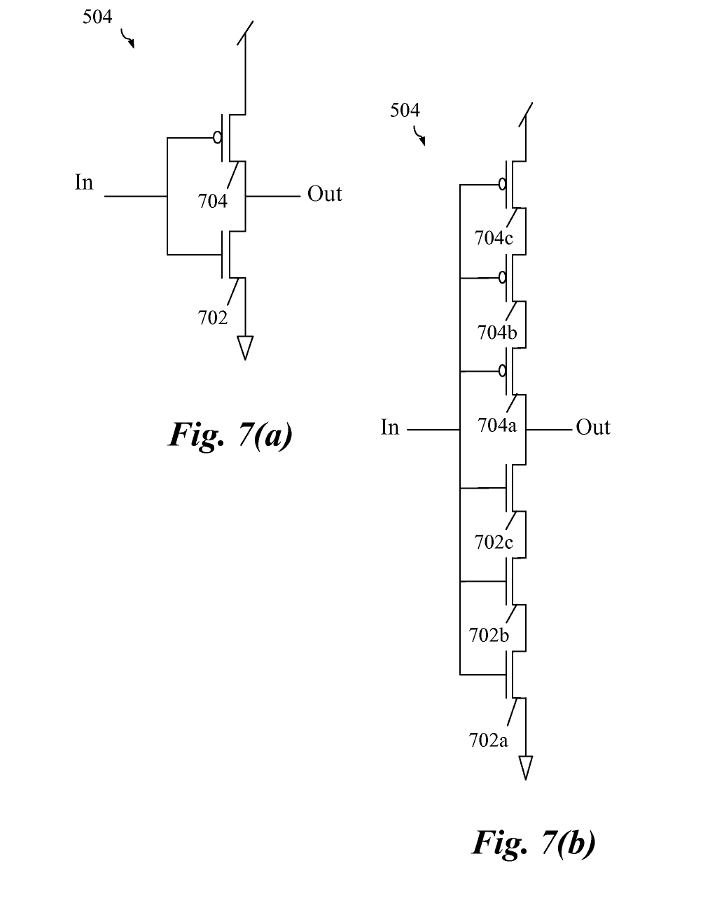

With respect to the balanced inverter design, the inverter 504 may have a single NFET 702 and single PFET 704 configuration as shown in FIG. 7(a). In this embodiment the inverter 504 has a small (minimum) channel area in order to capture process variations. For a given minimum defined channel length for both NFET and PFET devices, the NFET device 702 will have a width, Wn (e.g., 1 micron), while the PFET device 704 will have a width Wp some factor, X, of Wn (i.e., Wp=X*Wn) such that the N and P drive current for a given operating temperature will be balanced. Obviously, X is greater than 1 since the on current of an NFET of a given size is more conductive than the on current of a PFET of the same size. Thus, the PFET channel width is widened with respect to the NFET channel in order to nominally balance the on currents.

FIG. 7(b) is an alternative embodiment with respect to the balanced inverter design. As can be seen, the balanced inverter 504 may include multiple FET devices in a stacked configuration. For example, inverter 504 in this embodiment includes NFETs 702a, 702b, and 702c, as well as PFETs 704a, 704b and 704c. The channel length of the devices may still correspond to a minimum defined length, and the channel width of the PFETs 704a, 704b and 704c will be a factor of the channel length of the NFETs 702a, 702b, and 702c. The stacked device embodiment of FIG. 7(b) may be better suited for capturing chip mean process corner models and mitigating across chip line variations (ACLV).

The flow diagrams depicted herein are just one example. There may be many variations to this diagram or the steps (or operations) described therein without departing from the spirit of the invention. For instance, the steps may be performed in a differing order or steps may be added, deleted or modified. All of these variations are considered a part of the claimed invention.

While the invention has been described with reference to a preferred embodiment or embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A device comprising:
a silicon chip including circuit elements disposed thereon; and
a plurality of interleaved ring oscillators disposed on a surface of the silicon chip, the plurality of interleaved ring oscillators including a first interleaved ring oscillator, the first interleaved ring oscillator including a plurality of identical cells, wherein a first half of the plurality of identical cells are coupled to one another to form a clockwise ring and a second half of the plurality of identical cells are coupled to together to form a counter clockwise ring and wherein each cell in the first half is separated from another cell in the first half by a cell in the second half.

2. A method for determining correlated across chip variation, the method comprising:
placing a plurality of interleaved ring oscillators over the surface of a silicon chip in a predetermined pattern;
measuring the periods of oscillation of each interleaved ring oscillators;
based on the periods of oscillation of each interleaved ring oscillators, calculating a total across chip variation value;
based on the periods of oscillation of each interleaved ring oscillators, calculating an uncorrelated across chip variation value; and
calculating the correlated across chip variation value by subtracting the uncorrelated across chip variation value from the total across variation value.

3. The method of claim 2, wherein calculating the total across chip variation includes:
determining the mean of a clockwise period and a counter clockwise period for each of the interleaved ring oscillators;
calculating the unique differences between the mean periods; and
evaluating the distribution of the differences.

4. The method of claim 3, wherein calculating the uncorrelated across chip variation includes:
determining the difference of a clockwise period and a counter clockwise period for each of the interleaved ring oscillators; and
evaluating the distribution of the differences.

5. The method of claim 2, wherein each interleaved ring oscillator includes a plurality of identical cells, wherein a first half of the plurality of identical cells are coupled to one another to form a clockwise ring and a second half of the plurality of identical cells are coupled to together to form a counter clockwise ring and wherein each cell in the first half is separated from another cell in the first half by a cell in the second half.

6. The method of claim 5, wherein the clockwise ring further comprises:
a ring nand gate coupled to a first end of an oscillator portion of the clockwise ring;
a latch coupled to an output of the ring nand gate and a second end of the oscillator portion; and
an output buffer coupled to the second end of the oscillator portion.

7. A method of conforming modeled across chip variation data to actual correlated across chip variation values, the method comprising:
placing a plurality of interleaved ring oscillators over the surface of a silicon chip in a predetermined pattern;
measuring the periods of oscillation of each interleaved ring oscillators;
based on the periods of oscillation of each interleaved ring oscillators, calculating a total across chip variation value;
based on the periods of oscillation of each of the interleaved ring oscillators, calculating an uncorrelated across chip variation value;
calculating the correlated across chip variation value by subtracting the uncorrelated across chip variation value from the total across variation value;
correlating the modeled across chip variation data to the correlated across chip variation value;
determining if the modeled across chip variation data matches the correlated across chip variation value; and
modifying the modeled across chip variation data in the event that the modeled across chip variation data does not match the correlated across chip variation value.

8. The method of claim 7, wherein calculating the total across chip variation includes:
determining the mean of a clockwise period and a counter clockwise period for each of the interleaved ring oscillators;
calculating the unique differences between the mean periods; and
evaluating the distribution of the differences.

9. The method of claim 7, wherein calculating the uncorrelated across chip variation includes:
determining the difference of a clockwise period and a counter clockwise period for each of the interleaved ring oscillators; and
evaluating the distribution of the differences.

10. The method of claim 8, wherein each interleaved ring oscillator includes a plurality of identical cells, wherein a first half of the plurality of identical cells are coupled to one another to form a clockwise ring and a second half of the plurality of identical cells are coupled to together to form a counter clockwise ring and wherein each cell in the first half is separated from another cell in the first half by a cell in the second half.

11. An apparatus for directly measuring performance offset of NFET transistors with respect to PFET transistors in CMOS device processing, comprising:
a ring oscillator;
a balanced inverter having a input driven by the ring oscillator, wherein the balanced inverter is designed to be formed such that a current drive capability of one or more NFET devices of the inverter is substantially equal to a current drive capability of one or more PFET devices of the inverter at a given operating temperature; and
a capacitor coupled to an output of the inverter, with a voltage across the capacitor indicative of whether a skew exists between NFET device performance and PFET device performance.

12. The apparatus of claim 11, wherein the capacitor has a charge storage capability that exceeds the maximum current drive capability of the one or more NFET devices and PFET devices of the inverter, for a given operating frequency of the ring oscillator.

13. The apparatus of claim 11, wherein operating parameters for the ring oscillator, the inverter and the capacitor are selected in accordance with the following expression:
$$\frac{( {C}_{min} ) ( {V}_{int} / 2 )}{( {T}_{period \_ Max} / 2 )} > FETIon\_Max ;$$
wherein Cₘᵢₙ represents a minimum capacitance value for the capacitor, Vᵢₙₜ represents an internal power supply voltage used by the ring oscillator and the inverter, T_{period}_{_{—}}_{Max} corresponds to the speed or period of a maximum ring oscillator frequency, and FETIon_Max represents the exceeds the maximum current drive capability of the one or more NFET devices and PFET devices of the inverter.

14. The apparatus of claim 13, wherein:
$$\frac{( {C}_{min} ) ( {V}_{int} / 2 )}{( {T}_{period \_ Max} / 2 )}$$
exceeds FETIon_Max by at least a factor of 5.

15. The apparatus of claim 12, wherein for a common defined channel length for both NFET and PFET devices, the one or more NFET devices of the inverter have a width, Wn, and the one or more PFET devices of the inverter have a width Wp corresponding to a factor, X, of Wn, wherein Wp=X*Wn such that N and P drive currents for a given operating temperature of the inverter are designed to be balanced.

16. The apparatus of claim 11, wherein:
a voltage across the capacitor that exceeds half the value of an internal power supply voltage used by the inverter is indicative of a first type of skew where relative PFET current drive strength exceeds relative NFET current drive strength; and
a voltage across the capacitor that exceeds half the value of the internal power supply voltage used by the inverter is indicative of a second type of skew where relative NFET current drive strength exceeds relative PFET current drive strength.

17. A method of directly measuring performance offset of NFET transistors with respect to PFET transistors in CMOS device processing, the method comprising:
driving an input of a balanced inverter by a ring oscillator, wherein the balanced inverter is designed to be formed such that a current drive capability of one or more NFET devices of the inverter is substantially equal to a current drive capability of one or more PFET devices of the inverter at a given operating temperature; and
coupling a capacitor to an output of the inverter, with a voltage across the capacitor indicative of whether a skew exists between NFET device performance and PFET device performance.

18. The method of claim 17, wherein the capacitor has a charge storage capability that exceeds the maximum current drive capability of the one or more NFET devices and PFET devices of the inverter, for a given operating frequency of the ring oscillator.

19. The method of claim 17, wherein operating parameters for the ring oscillator, the inverter and the capacitor are selected in accordance with the following expression:
$$\frac{( {C}_{min} ) ( {V}_{int} / 2 )}{( {T}_{period \_ Max} / 2 )} > FETIon\_Max ;$$
wherein Cₘᵢₙ represents a minimum capacitance value for the capacitor, Vᵢₙₜ represents an internal power supply voltage used by the ring oscillator and the inverter, T_{period}_{_{—}}_{Max} corresponds to the speed or period of a maximum ring oscillator frequency, and FETIon Max represents the exceeds the maximum current drive capability of the one or more NFET devices and PFET devices of the inverter.

20. The method of claim 17, wherein for a common defined channel length for both NFET and PFET devices, the one or more NFET devices of the inverter have a width, Wn, and the one or more PFET devices of the inverter have a width Wp corresponding to a factor, X, of Wn, wherein Wp=X*Wn such that N and P drive currents for a given operating temperature of the inverter are designed to be balanced.
